(19) United States
(12) Patent Application Publication
(10) Pub. No.: US 2011/0317391 A1
(43) Pub. Date: Dec. 29, 2011

(54) BUILDING BLOCK

(76) Inventor: Ding-Yu PENG, Jhubei City (TW)

(21) Appl. No.: 12/824,648

(22) Filed: Jun. 28, 2010

(51) Int. Cl. H05K 7/04

(52) U.S. Cl. 361/809

(57) ABSTRACT

A building block includes a body. The external surfaces of the body are respectively formed with at least one active side and at least one passive side. The active side is formed with an active positive and an active negative that are magnetic. The passive side is formed with a passive positive and a passive negative. The passive positive is magnetically absorbed and fixed by the active positive; the passive negative is magnetically absorbed and fixed by the active negative. A positive lead wire is between the active positive and the passive positive. A negative lead wire is between the active negative and the passive negative. A load is connected between the positive lead wire and the negative lead wire. When the building blocks are assembled, the passive side is absorbed by the active side. The loads in the blocks are driven and thus the blocks become more diverse.

### BACKGROUND OF THE INVENTION

1. Field of the Invention

This invention relates to a building block.

2. Description of the Prior Art

A conventional building block is formed with a body. The body is formed with determined lugs and grooves that may be wedged to each other. With the lugs and grooves that are wedged together, the bodies may be combined with each other and thus the building blocks may be randomly formed. The building blocks are combined and vary almost in shape, such as square, round and the like as a basic 3D form, and the building blocks are positioned and vary for the effect of shape variation. The building blocks are quite limited in usage.

Consequently, because of the technical defects of described above, the applicant keeps on carving unflaggingly through wholehearted experience and research to develop the present invention, which can effectively improve the defects described above.

### SUMMARY OF THE INVENTION

A building block according to the present invention is formed with a body. The external surface sides of the body are respectively formed with at least one active side and at least one passive side. The active side is formed with an active positive and an active negative. Both the active positive and the active negative are magnetic. The passive side is also formed with a passive positive and a passive negative. The passive positive may be magnetically absorbed and fixed by the active positive. The passive negative may be magnetically absorbed and fixed by the active negative. A positive lead wire is provided between the active positive and the passive positive. A negative lead wire is also arranged between the active negative and the passive negative. A load is connected between the positive lead wire and the negative lead wire.

In the present invention, for combining the building blocks, the active side of the body may be made to magnetically absorb the passive side to connect to each other and drive the load in the building block so that the shape of building blocks may vary and different effects may be brought by the internal load for increasing the entertainment and variation of the assembly.

### BRIEF DESCRIPTION OF THE DRAWINGS

FIG. 1 is a 3D view of the appearance of a building block according to the present invention;

FIG. 2 is a 3D exploded view of the building block according to the present invention;

FIG. 3 is a schematic assembly view of the building block according to the present invention; and

FIG. 4 is a sectional view of the building block in another embodiment of the present invention.

### DETAILED DESCRIPTION OF THE PREFERRED EMBODIMENTS

Now, the present invention will be described more specifically with reference to the following embodiments. It is to be noted that the following descriptions of preferred embodiments of the present invention are presented herein for purpose of illustration and description only; it is not intended to be exhaustive or to be limited to the precise form disclosed.

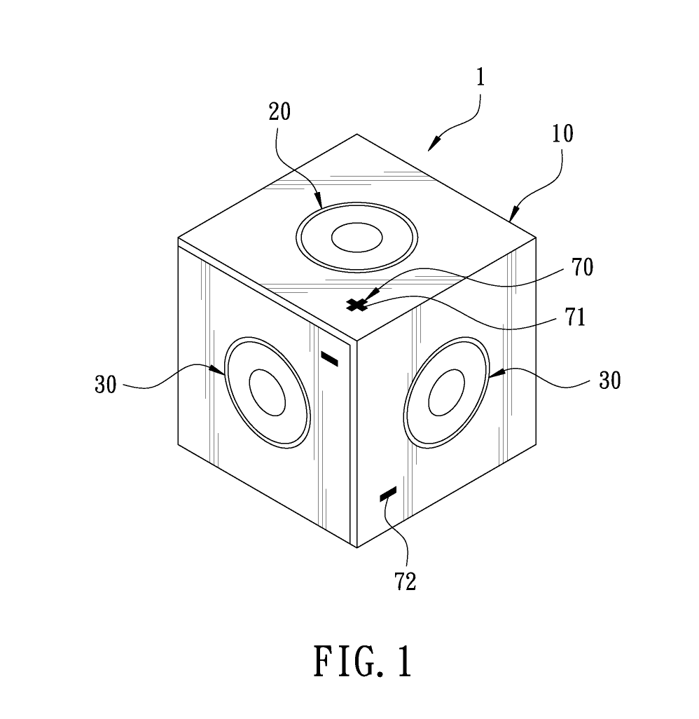

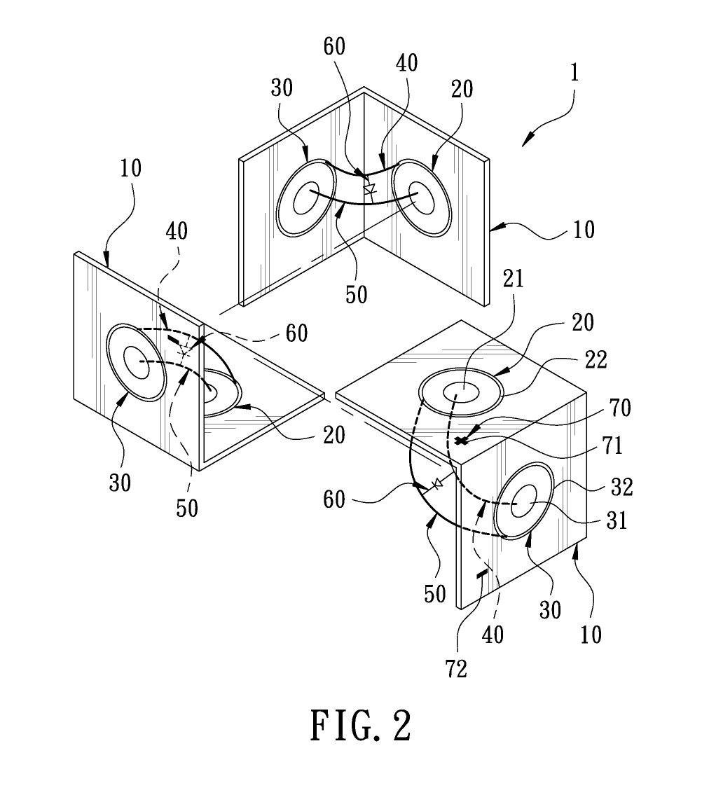

In a preferred embodiment illustrating a building block according to the present invention, with reference to FIGS. 1 and 2 as a 3D appearance view and a 3D exploded view of the present invention, the building block mainly comprises a body 1.

The body 1 is formed with three L-shaped plates 10 that are combined with each other. The external surface side of plate 10 that are opposite to each other are respectively formed with an active side 20 and a passive side 30.

The active side 20 is formed with an active positive 21 and an active negative 22. The active positive 21 and the active negative 22 are formed in a concentric circle. Both the active positive 21 and the active negative 22 are magnetic. In the embodiment, the active positive 21 and the active negative 22 are identical magnetic. The active positive 21 and the active negative 22 may be also opposite magnetic. The passive side 30 is also formed with a passive positive 31 and a passive negative 32. In the present invention, the passive positive 31 and the passive negative32 may be metallic that are magnetically absorbed by the active side 20. The passive positive 31 and the passive negative 32 may be formed with magnetic poles of which the polarities are opposite to the active positive 21 and active negative 22. The passive positive 31 and the passive negative 32 are also formed in the concentric circle as the active positive 21 and the active negative 22 so that the passive positive 31 may be magnetically absorbed by the active positive 21. The passive negative 32 may be magnetically absorbed and fixed by the active negative 22.

A positive lead wire 40 is provided between the active positive 21 and the passive positive 31. A negative lead wire 50 is also arranged between the active negative 22 and the passive negative 32. A load 60 is connected between the positive lead wire 40 and the negative lead wire 50. In the embodiment, the load 60 is a LED that may also sound or vibrate. The three plates 10 may be combined into a cubic building block body 1.

Further, in order to easily confirm the positions of the active side 20 and passive side 30, the body 1 is formed with a mark portion 70. The mark portion 70 comprises a first mark unit 71 and a second mark unit 72. The first mark unit 71 is formed on the active side 20, while the second mark unit 72 is formed on the passive side 30, which may be relatively formed with marks in graph or color.

In order to further make apparent the structural features, applied skill and manners, and expected effects according to the present invention, what are applied in this invention are in detail described, and it is thus believed that the present invention is thoroughly and concretely apparent.

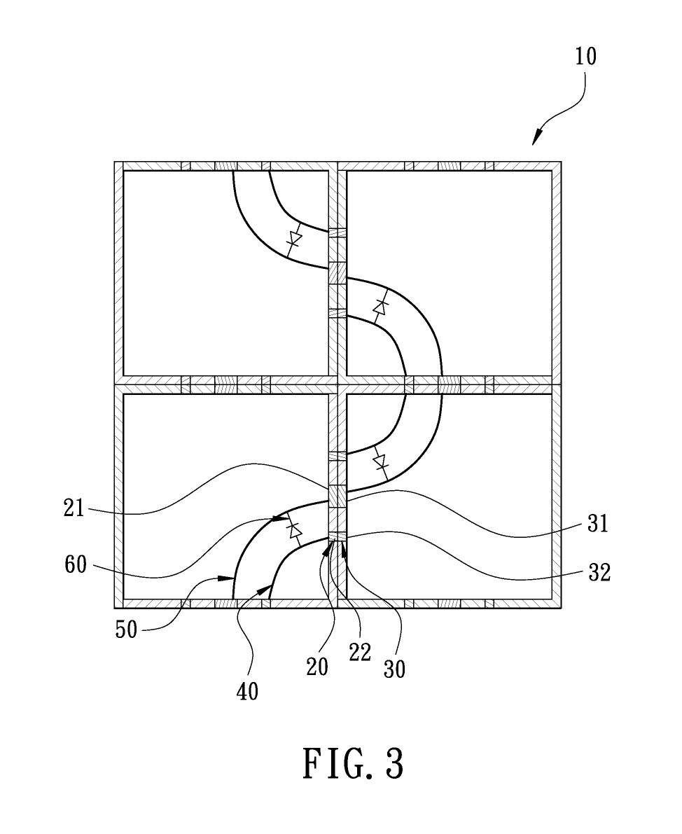

With reference to FIG. 3 as a schematic assembly view of the present invention, for assembling the building block body 1, the active side 20 may be connected to the passive side 30, and thus the active side 20 actively absorbs and fixes the passive side 30. The active positive 21 is then connected to the passive positive 31 and the active negative 22 is connected to the passive negative 32 so that the positive lead wires 40 and negative lead wires 50 between the building block bodies 1 may be connected to each other, and then the breakover effect is caused. When the building block bodies 1 are assembled, a loop is formed. When the building block bodies 1 are turned ON, the load 60 may be driven to light up. Besides, the building block body 1 is formed with three different plates 10, so the color of load 60 may vary or different effects may be brought by different loads 60 that sounds or vibrates. Thus, the shape of building block body 1 when being assembled may vary, and different effects also are brought when the load 60 is driven for more fun.

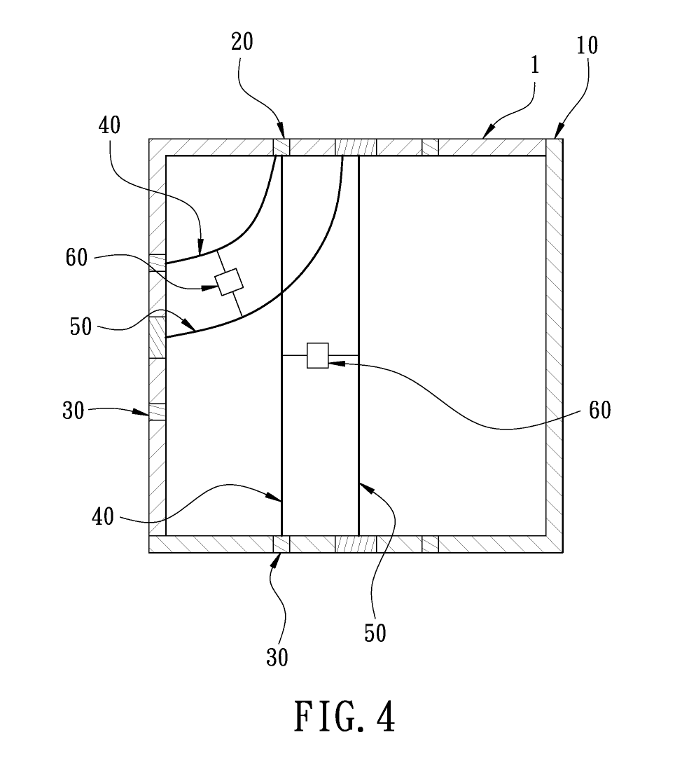

With reference to FIG. 4 as a schematic view of another embodiment of the present invention, the main structure is the same as that described in the former embodiment, so unnecessary details are not given here. The plate 10 of the body 1 comprises an active side 20 and two passive sides 30. Thus, when the active side 20 is turned ON, the passive sides 30 may be respectively combined with two different active sides 20 and the loads 60 may bring different effects at the same time for increasing the entertainment. Further, the active side 20 and the passive side 30 may exchange the positions, and a load 60 that is turned ON may be selected during operation for adding more different options.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A building block, being formed with a body, the external surface sides of the body being respectively formed with at least one active side and at least one passive side, the active side being formed with an active positive and an active negative, both the active positive and the active negative being magnetic, the passive side being also formed with a passive positive and a passive negative, the passive positive being magnetically absorbed and fixed by the active positive, the passive negative being magnetically absorbed and fixed by the active negative, a positive lead wire being provided between the active positive and the passive positive, a negative lead wire being also arranged between the active negative and the passive negative, and a load being connected between the positive lead wire and the negative lead wire.

2. The building block according to claim 1, wherein the passive positive is metallic that is magnetic for absorption.

3. The building block according to claim 1, wherein the passive negative is metallic that is magnetic for absorption.

4. The building block according to claim 1, wherein the passive positive is formed with a magnet, being opposite to the magnetic pole of active positive.

5. The building block according to claim 1, wherein the passive negative is formed with a magnet, being opposite to the magnetic pole of active negative.

6. The building block according to claim 1, wherein the load is a light-emitting diode (LED).

7. The building block according to claim 1, wherein the active positive and the active negative on the surface of body are the same in magnetism.

8. The building block according to claim 1, wherein the active positive and the active negative on the surface of body are the same in magnetism.

9. The building block according to claim 1, wherein the building block body is formed with a determined number of plates on which the active side and the passive side are formed.

10. The building block according to claim 1, wherein the body 1 is formed with a mark portion.

11. The building block according to claim 10, wherein the mark is a graph.

12. The building block according to claim 10, wherein the mark is a color.
